(19) United States
(12) Patent Application Publication
(10) Pub. No.: US 2025/0016933 A1
(43) Pub. Date: Jan. 9, 2025

(54) VIBRATORY THREADED FASTENER REMOVAL SYSTEM

(71) Applicant: Garner Products, Inc., Roseville, CA (US)

(72) Inventors: Ronald Stofan, Folsom, CA (US); Ryan Moore, Rocklin, CA (US); Mason Bender, Roseville, CA (US); Steven Montesanto, Auburn, CA (US); Todd Linville, Citrus Heights, CA (US)

(21) Appl. No.: 18/888,645

(22) Filed: Sep. 18, 2024

Related U.S. Application Data
(63) Continuation-in-part of application No. 18/368,728, filed on Sep. 15, 2023.
(60) Provisional application No. 63/406,856, filed on Sep. 15, 2022.
(60) Provisional application No. 63/450,818, filed on Mar. 8, 2023.

(51) Int. Cl. H05K 3/22

(52) U.S. Cl. CPC H05K 3/22; H05K 2203/176

(57) ABSTRACT

A retainer holds an assembly including multiple sub-components which are held together by screws or other threaded fasteners. One example assembly is a hard disk with a printed circuit board to be removed. A source of vibrational energy is brought adjacent to the assembly and activated to impart vibrational energy into the assembly. The vibrational energy is sufficient to cause the screws or other threaded fasteners to become unthreaded from holes in which they were originally located. Separation of the components from each other is thus facilitated. A machine is also disclosed for at least partial automation of the threaded fastener removal process. The machine operates within a case for management of sound caused by the operation of the machine according to one method of this invention. The vibrational energy can also cause sub-components to be removed which have been attached by bonding and/or welding.

### CROSS-REFERENCE TO RELATED APPLICATIONS

This application is a continuation-in-part of U.S. patent application Ser. No. 18/368,728 filed on Sep. 15, 2023, which claims benefit under Title 35, United States Code § 119(e) of U.S. Provisional Application No. 63/406,856 filed on Sep. 15, 2022 and U.S. Provisional Application No. 63/450,818 filed on Mar. 8, 2023.

### FIELD OF THE INVENTION

The following invention relates to methods and systems for removing threaded fasteners. More particularly, this invention relates to methods and systems for removing screws and other threaded fasteners that are holding assemblies together, such as components within electronic devices, and especially removal in a manner which does not require manually torquing the threaded fasteners.

### BACKGROUND OF THE INVENTION

Many electronics products include multiple components which are screwed together. In many instances a housing is provided and different components of such products are screwed to the housing or otherwise provided within the housing. In other instances different components are screwed to each other or to other supports.

When electronics products have reached the end of their useful life, either due to wearing out, becoming obsolete, containing data which is to be erased/destroyed, or for other reasons, it is often desirable for them to be further managed during the recycling process. Such management can include separation of different components from each other and/or from a housing (or other support) so that they can be separately recycled to recover the materials from which they are made or for other reasons. In some instances, at least some components of the electronics products can be harvested and reused in their current form, rather than being taken down to their raw materials. In other instances data destruction may call for specific components of the electronics products to be shredded or degaussed or otherwise processed to ensure that all data is removed therefrom.

Regardless of the underlying reason for the electronics products reaching the end of their useful life, in many instances it is desirable to separately process different components of the electronics products in different ways. When at least some such components are screwed to the housing or screwed to other components, such separating involves the tedious and sometimes difficult process of removing screws or other threaded fasteners. Some such screws are quite small, making their removal further challenging.

As one example of such a component which often benefits from being separated from other components within an electronics product at the end of the product's useful life, printed circuit boards (PCBs) are often screwed to a housing or other components (hard disks as one example), which screws need to be removed so that the PCB can be handled in a desired manner. In many instances, standoffs extend from the housing and have a threaded bore into which the screws are placed, after passing through holes at appropriate corresponding locations in the PCB.

For a worker to remove such a PCB, an appropriate screwdriver is identified, and then a repeated twisting motion applied to the screwdriver while a tip of the screwdriver is accessing the head of the screw. The action causes unscrewing and removal of the screws, one by one. It is not uncommon for half a dozen or more screws to be holding a PCB in place. After multiple electronics products have been so disassembled, the worker typically experiences significant fatigue from the repetitive stresses associated with screw removal. Powered screw drivers can be of some assistance, but tend to be difficult to use on the small screws which typically secure PCBs, and still require significant effort by the worker.

Accordingly, a need exists for improved and at least semi-automated methods for screw removal and for separation of components from one another and/or from a housing within electronics products. Such a system would benefit from also being able to separate components from each other which are fastened together with other mechanical fasteners or bonded or welded together. For instance, some helium drives have welded seams to prevent the helium from leaking, and such seams would also be beneficially split in an automated or semi-automated fashion to assist in component separation.

Prior art research into threaded fasteners has tended to focus on how to keep threaded fasteners from becoming unintentionally unthreaded. Very undesirable and even disastrous consequences can occur when threaded fasteners unscrew themselves unintentionally. Such research including research into what has become known as the “Junker Effect” has identified causes of threaded fastener inadvertent unscrewing. Such causes are primarily lateral forces between separate components held together by the threaded fastener or lateral forces between the threaded fastener and a threaded bore into which the threaded fastener is located. Lateral forces are generally described as forces which are substantially perpendicular to a central axis of the threaded fastener. Thermal expansion and contraction forces have secondarily been identified as causing threaded fastener unscrewing. Surprisingly, vibration has not been seen as a significant contributor to unintended fastener unscrewing.

As a basic mechanism, threads of a threaded fastener have surfaces which are in contact with female threads in a corresponding structure, such as a threaded bore or nut. When static friction forces between these surfaces are greater than forces/torque which would cause the threaded fastener to become unscrewed, the threaded fastener will remain in position. However, when this static friction between the surfaces is overcome, such forces will be able to unscrew the threaded fastener. These forces can be gravity forces, electric forces, magnetic forces, or loads of various types applied directly to the fasteners or applied to structures held together by the fasteners. Such loads can include thermal expansion/contraction loads, pressure loads, tension loads, and any other of a variety of other loads (or combinations of loads or other forces) acting upon the threaded fastener or structures adjacent to the threaded fastener.

Considering concepts of entropy, and a general trend toward disorganization, and recognition that it is more difficult for a threaded fastener to thread itself than to unthread itself in response to random loads and other forces, threaded fasteners such as screws, can become unscrewed merely by applying forces which can overcome the static friction forces between the threaded surfaces of the screws or other threaded fastener, to cause screws or other threaded fasteners to be removed. Entropy resists such random forces causing the screws or other fasteners to “self-tighten.”

While generalized vibrational energy has not been found in prior research to be particularly a cause of unintended screw or other threaded fastener removal, the inventors have discovered that application of vibrational energy to assemblies of components which are screwed together is highly effective in removing screws holding components of the assembly together. In fact, such screws often “jump” out of their threaded bores with such action on the screws typically occurring very rapidly. This was surprising when research into unintended threaded fastener removal tended to recognize forces and conditions other than vibration as being primarily the cause of unintended threaded fastener removal. Thus, while somewhat counterintuitive, it appears from the inventors' discovery that vibrational energy is not a primary reason for unintended threaded fastener removal. However, intentional application of vibrational energy upon an assembly of components can surprisingly be very effective in rapidly and efficiently removing screws or other threaded fasteners, such as when disassembling components which have been attached together by threaded fasteners. Experimentation of the inventors has also shown that components welded together or bonded together with an adhesive or other bonding agent can also be readily separated from each other by imparting vibrational energy thereon. While high levels of vibrational energy can in some instances be most effective, energy levels (and frequencies) can be selected which cause threaded fastener removal but which avoid or minimize damage to the components being disassembled from the assembly.

### SUMMARY OF THE INVENTION

With this invention, a screw removal tool and method are provided which avoid utilization of a screwdriver and the associated potential for repetitive stress injuries, and save time for workers who would otherwise be tasked with screw removal. The tool generally includes two parts including a retainer and at least one vibratory and/or shock input tool.

The retainer in one embodiment has a floor, and back wall and two side walls, with an upper and forward side of a central space being left at least partly open. An electronics device which has a component associated therewith which is attached with screws either to other components or to a housing, has the retainer sized to support the electronics device therein. Enough clearance is provided around the central space to allow for easy insertion and removal of the device into a central space of the retainer. In one example, the electronics device is a hard drive which includes a spinning hard disk, read/write hardware, a printed circuit board (PCB) and a housing, with the PCB screwed to the housing with a plurality of screws.

The central space of the retainer preferably has a width between side walls similar to a longest dimension of the hard disk (for other electronics devices, the retainer can be adapted to the size/shape of such other devices). A floor of the retainer has a depth from a front edge to a back wall which is similar to a second largest dimension of the hard disk. A height of the side walls and the back wall is preferably greater than a thickness of the hard disk. The hard disk can conveniently be placed into the central space with screw heads facing upwardly and substantially unobstructed from above. Such loading could occur automatically through some form of robotic machine, or could occur manually by a worker placing the hard disk into the central space of the retainer.

As one option, the side walls can be at least partially replaced with inlet and outlet chutes which allow a series of hard drives or other devices to be passed efficiently in series into the central space for treatment and then out of the central space. The back wall can in one embodiment be spring coupled to a more rigid reference surface, so that physical failure of parts of the device being treated are less likely to occur, because shock/vibration energy is absorbed and/or attenuated at this rear surface.

A vibratory input tool is then brought adjacent to the housing of the hard disk (or some other portion of the hard disk or other electronics device or other assembly), such as on a forward most portion of the hard disk, extending from an exposed forward side of the open space of the retainer (or recessed somewhat into this open front side of the retainer). As one option, two or more vibratory tools can be provided or one tool with multiple heads can be provided, so that input of shock and/or vibration to the device occurs at two or more locations. Physical contact between the tool and the assembly facilitates vibration to be transferred to the assembly. The vibratory input tool could be any of a variety of tools which include a head or other vibratory output which vibrates relative to a body of the tool. Preferably, this head is somewhat in the form of a hammer head with a flat face defining a portion of the vibratory input tool most distant from the body. A jack hammer with such a hammer head output is one such tool, typically of a handheld size. In one embodiment, the retainer is affixed to a jig and the jig also holds the vibrating body of the vibratory tool, with the hammer head at the distal end of the vibratory input tool adjacent to the forward facing side of the housing that is within the retainer.

The vibratory input tool has its head brought into contact with the housing, and the vibratory input tool is then powered, causing vibratory energy to vigorously vibrate the housing of the electronics device. Typically, the vibrating structure of the vibratory input tool includes an AC motor powered by an AC power supply, such as standard power from the electricity grid of 120 or 240 V, 60 Hz and drawing a typical current for such tools, such as between 1 amp and 30 A, or potentially greater or less current, depending on the size of the tool. In one embodiment, vibration and/or shock is generated by rotation of an eccentric mass by the electric motor.

This vibratory energy causes the housing to vibrate. The screws holding the PCB to the housing and/or other components of the electronics device vibrate and are caused to work their way out of the holes and out of the standoffs or other threaded structures to which the screws attach. In fact, experiments have shown that the screws have a tendency to violently fly up and away from the printed circuit board after a matter of less than 5 to 10 seconds. The PCB is then free to be separately handled, removed and processed from other components and separate from the housing. As an option, the vibratory input tool can have a variable output so that it initially imparts a high energy “shock” to the entire device. This can help to initially loosen the screws slightly so that the screws are more responsive to vibratory energy at lower levels, while minimizing unwanted structural failure of components of the device being treated.

While the exact mechanism for causing rapid screw removal through vibratory tool input is not entirely understood, it is generally believed that the screws have a natural frequency at which they vibrate, and that this natural frequency is different from the housing and/or other components to which the screw is fastened. This causes the screws and the housing to vibrate in a distinct manner. Generally, the screws are the tightest when the largest number of turns of the screw are engaging female threads of a screw support, such as below a hole in the PCB (such as within a standoff). As distinct vibration of the screw and housing affect the screw and housing differently, the screw tends toward a higher position within the female threaded bore, as this is a movement towards a state requiring lesser force/energy. Stated alternatively, once the screw has vibrated out of the threaded bore half a turn, it takes more energy to insert the screw deeper into the threaded bore than to remove the screw out of the threaded bore. Hence, as random vibratory energy (or specific selected frequency vibratory energy) is encountered by the housing and associated threaded bores, and by the screw, random differential motions therebetween cause the screw to tend toward being looser and looser, rising up out of the threaded bore until the screw is entirely free.

Performance of this invention can be theoretically optimized by selecting a vibratory frequency of optimum effectiveness. In one embodiment, such optimum effectiveness involves having the vibratory frequency match a natural frequency of the screw, or some harmonic thereof. In another embodiment, this invention can be optimized by selecting a vibratory frequency of optimum effectiveness in the form of having the vibratory frequency match a natural frequency of the threaded bore, standoff and/or housing into which the screw is fastened, or some harmonic thereof. In another embodiment, a vibratory frequency is selected which is an average of natural frequencies of the screw and the threaded bore. In another embodiment, for optimal performance, the vibratory frequency and amplitude are selected to correlate with the vibratory frequency inputs of both the natural frequency for the screw and the natural frequency for the threaded board, or harmonics thereof. As an option, higher energy and/or amplitude of vibration can initially be provided, such as in the form of a pulse, to shock the entire device. This can help to initially free up the screws by overcoming static friction forces between the threads of the screw and threaded hole. Then lower energy and/or amplitude can continue to be applied for screw removal (and other disassembly).

In one embodiment, a variable frequency vibrator tool is provided and a user utilizes trial and error operating a vibratory tool at different frequencies to determine which frequency most rapidly and/or effectively causes the screws to be removed. This frequency can then be marked and provided as a most desired setting when removing screws of a similar type from electronics devices of a similar type, so that the tool is optimized to provide different vibrational frequencies for different electronics components, based on prior experience. In a similar manner to adjusting frequency, amplitude of the vibration can also be modified in one embodiment utilizing a vibratory tool which allows for adjustment of amplitude of vibration provided by the vibratory input tool. Again, trial and error can be utilized to adjust the amplitude until optimal results are achieved. This amplitude can then be marked and reused for similar electronics devices for efficient screw removal. A combination of selected frequency and amplitude can also be utilized as another option for efficient screw removal.

While the retainer of one embodiment of this invention has an open top, typically to allow the screws to freely come out of the PCB, a user's hand typically rests on the hard disk or other electronics device to hold it within the retainer during utilization of the vibratory input tool, and keeping the hard disk or other electronics device within the retainer. As an alternative, some form of clamp or stop can be removably positionable to hold the electronics device in position within the retainer during the screw removal process. Typically, such a clamp or other device does not hold the housing of the hard disk tightly, but just provides enough retention to keep the hard disk from vibrating up out of the retainer entirely during use of the tool. Also, a side of the retainer opposite the vibratory input tool typically includes a backing plate which is typically spring loaded and keeps the hard disk adjacent to the vibratory input tool.

In one embodiment, the entire process is automated. Hard disks or other electronics components are inserted into the machine using appropriate robotic arms, conveyors, chutes or other conveyance mechanisms, to place the hard disk within a retainer. Here vibratory tools are brought adjacent to a housing or at least one of the components within the electronics device and the vibratory input tool is then caused to commence operation. When the screws fly off they can be automatically captured (such as by falling into a screw harvest receptacle). The screws can then be reused or recycled. The PCB or other component being removed is then separately collected, such as with an appropriate robotic arm, or through some other automated mechanism for further handling of the PCB or other competent to be removed separate from other components of the electronics device. Further processing of the PCB and portions thereof (or other removed components) can then occur, while the housing or remaining components can also be separately processed.

In addition to screw removal, vibratory energy provided by this invention can also provide for non-screw disassembly as well. For instance, components which are bonded together or welded together can be vibrated apart by application of vibratory energy according to this invention. Also, other mechanical fasteners other than screws can be loosened and/or removed by application of such vibratory energy. For instance, a hard disk can have magnets which are bonded or otherwise fastened to portions of the hard drive removed for re-use or recycling by use of the vibratory tool of this invention.

In certain embodiments, the item/assembly to be disassembled is routed vertically downward through a machine which has the hammers oriented within a central operational zone thereof. The hammers would typically be oriented substantially horizontally adjacent to a pathway for items passing down into the operational zone from a feed zone above the operational zone. An input chute can be provided to allow for items to be fed into the feed zone. A top gate, such as in the form of a trap door, can be provided at a divider between the feed zone and the operational zone. When the top gate is opened, items fall down from the feed zone into the operational zone adjacent to the hammers (or at least one hammer). The hammer and associated backstop opposite the hammer, with the item therebetween, can then be brought into contact with the item to impart vibrational energy into the item for threaded fastener removal and other disassembly.

Thereafter, the item and removed components can fall down into a discharge zone. In one embodiment, a lower gate is provided in a divider between the operational zone and the discharge zone. A funnel can capture the item (or disassembled parts thereof) and component, such as feeding into a discharge chute within the discharge zone for removal of the item and separated components thereof out of the machine.

### OBJECTS OF THE INVENTION

Accordingly, a primary object of the present invention is to provide a method for removing threaded fasteners so that items screwed together can be separated from each other, and especially methods which do not require manual torquing of the threaded fastener.

Another object of the present invention is to provide a machine for processing assemblies including multiple components screwed together, to separate the components from each other in an automated fashion.

Another object of the present invention is to provide a system for separating components of an electronic device or other assembly through input of vibratory energy.

Another object of the present invention is to provide a method for removing threaded fasteners which includes vibrating the threaded fasteners to cause them to be unscrewed.

Another object of the present invention is to provide a method for removing multiple threaded fasteners simultaneously with as few as one threaded fastener removal apparatus.

Another object of the present invention is to provide a machine which transports an assembly of components from an input location to an output location in an automated fashion and which causes separation of components from each other for separate handling downstream of the output location.

Another object of the present invention is to avoid repetitive stress injuries of personnel tasked with removing threaded fasteners by providing a method and or an apparatus which removes threaded fasteners without requiring manual torquing of the fasteners.

Another object of the present invention is to provide a machine which uses vibratory energy to remove threaded fasteners holding separate components of an assembly together and which machine absorbs and/or contains sound associated with machine operation below selected threshold maximum values for an area near the machine, such as maximum allowable sound for various work environments, with and without hearing protection.

Other further objects of the present invention will become apparent from a careful reading of the included drawing figures, the claims and detailed description of the invention.

### BRIEF DESCRIPTION OF THE DRAWINGS

FIG. 1 is a perspective view of a generalized retainer for an assembly of components, exemplified in the form of a hard disk including a printed circuit board (PCB) fastened thereto with screws, and in the midst of being placed into the retainer.

FIG. 2 is a perspective view similar to that which is shown in FIG. 1, but after the hard disk has been fully placed into the retainer.

FIG. 3 is a perspective similar to that which is shown in FIG. 2, but with a vibratory input tool brought near an outer housing of the hard disk for input of vibrational energy.

FIG. 4 is a perspective view similar to that which is shown in FIG. 3, but with the vibratory input tool vibrating to input vibratory energy into the hard disk.

FIG. 5 as a perspective view of that which is shown in FIG. 4 and illustrating how the screws holding the PCB to the hard disk are flying out of their holes in response to the imparted vibratory energy.

FIG. 6 is a perspective view of that which is shown in FIG. 5, but with the hard disk having been removed from the retainer and the PCB easily liftable off of the hard disk for separation, and with the screws separated from the assembly.

FIG. 7 as a perspective view of a machine configured to automate at least portions of an overall process of separating components of an assembly which are coupled together; and illustrating how the assemblies, such as hard disks, are processed from an input chute to an output chute.

FIG. 8 is a perspective view of an alternate embodiment machine to that shown in FIG. 7.

FIG. 9 is a perspective view of a carrier for use in the machine of FIG. 8 and featuring two slots for holding two hard disks or other items.

FIG. 10 is a perspective view of a single slot carrier for use in the machine of FIG. 8.

FIG. 11 is a perspective view of a batch loader for use with the machine of FIG. 7 or 8.

FIG. 12 is a perspective view from below of a backstop assembly featuring a block supported by a housing through springs and configured to keep a hard disk or other item abasing hammers within the machines of FIG. 7 or 8.

FIG. 13 is a perspective view of a machine operating according to a method of this invention and housing the vibratory input tool of this invention, generally corresponding with a configuration of the vibratory input tool as shown in FIG. 7, and with the machine in an embodiment where a pathway for items to be disassembled passes vertically past the vibratory input tool, at least partially under force of gravity therethrough.

FIG. 14 is a perspective view of an alternative embodiment of that which is shown in FIG. 13, featuring an operational area generally corresponding with the embodiment of FIG. 8.

### DESCRIPTION OF THE PREFERRED EMBODIMENT

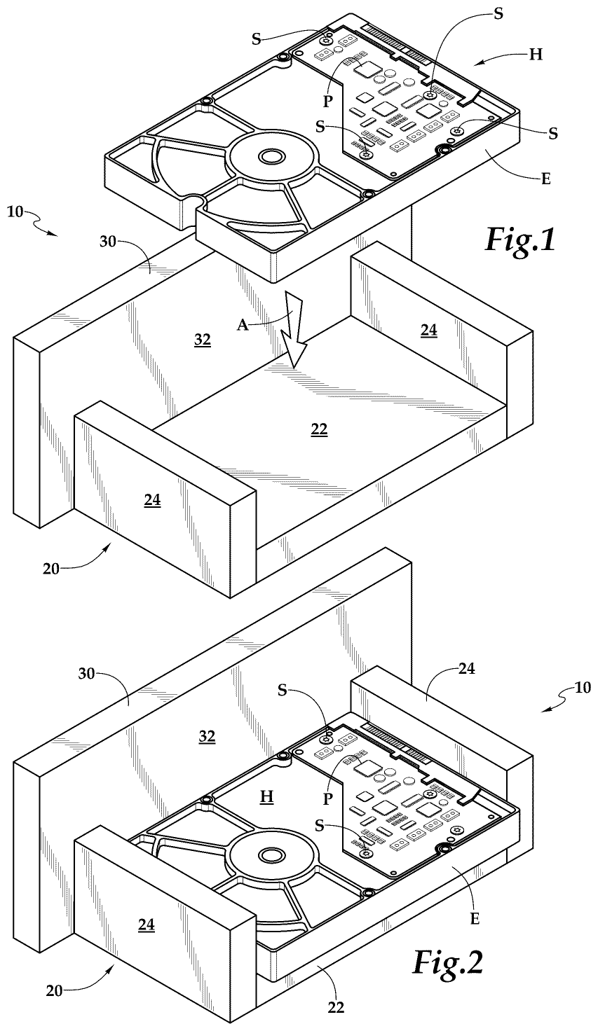

Referring to the drawings, wherein like reference numerals represent like parts throughout the various drawing figures, reference numeral 10 is directed to a system for threaded fastener removal (FIGS. 1-5). With this system 10, a vibratory input tool 40 imparts vibration upon a hard disk H or other assembly of components. The vibratory energy causes a printed circuit board (PCB) P or other component of the assembly to be removed from the assembly by the vibratory energy, causing screws S or other threaded fasteners to become unthreaded. Vibratory energy can also optionally cause bonded and/or welded components to be separated from an overall assembly for convenient removal of components from an assembly, such as for separate processing thereof.

In essence, and with particular reference to FIGS. 1-5, basic details of this invention are described according to an example embodiment. The system 10 generally includes a retainer 20 for holding a hard disk H or other assembly of components that are initially held together by threaded fasteners. The system 10 also includes a vibratory input tool 40 which is configured to come into contact with the hard disk H and impart vibratory energy thereupon, sufficient to cause threaded fasteners to become unthreaded. A backstop 30 of the retainer 20 is oriented opposite the vibratory input tool 40, with the backstop 30 helping to keep the hard disk H in position during operation thereon by the vibratory input tool 40 and also to absorb and isolate excess vibratory energy from surrounding structures.

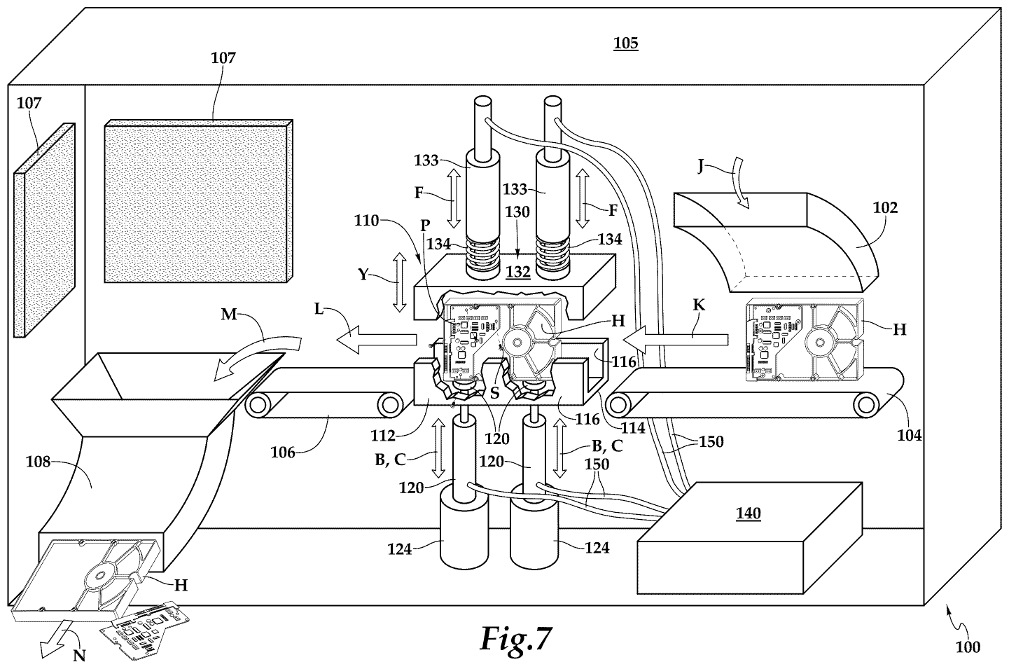

In one embodiment, the system 10 is implemented through a vibratory threaded fastener removal machine 100 (FIG. 7). This machine 100 includes an operational area 110 which functions similar to the system 10 (FIGS. 1-5), but in an at least semi-automated fashion. Hammers 120 impart vibrational energy upon the hard disk H or other assembly of components passing through the operational area 110 of the machine 100. A backstop 130 keeps the hard disk H adjacent to the hammers 120 and helps to absorb excess vibrational energy. A pneumatic source 140 powers the hammers 120 and the backstop 130 in this example embodiment, through air supply lines 150.

More specifically, and with initial reference to FIGS. 1-6, particular details of the system 10 of this invention, as well as a method of its operation, are described. The retainer 20 of the system 10 is preferably configured to hold a hard disk H or other assembly of components which is to be acted upon to cause the components to separate from each other. A hard disk H (FIG. 6) provides one assembly made up of different components which can be removed from each other utilizing the system 10 and associated method of this invention. The hard disk H generally includes a housing E which contains various sub-components therein. Typically one such sub-component is a PCB P, which is typically attached to other components or the housing E of the hard disk H through threaded fasteners such as screws S. Typically, these screws S pass through holes G in the printed circuit board P and also into threaded bores I which are attached at least indirectly to the housing E of the hard disk H. Other assemblies to be disassembled according to this invention are typically similarly held together with screws S or other threaded fasteners.

The various structures which make up the hard disk H or other assembly are generally substantially rigid structures. Vibrational energy imparted upon one portion of such assemblies thus tends to be transmitted without significant dissipation throughout the entire assembly either through carefully selecting vibrational frequencies or by selecting amplitude of sufficient magnitude (or some combination thereof). Threaded fasteners can thus be caused to unthread themselves and to allow for separate components to be removed from each other.

The retainer 20 in the embodiment disclosed in FIGS. 1-5 includes a floor 22 and sidewalls 24. Dimensions of the floor 22 and sidewall 24 are generally selected so that a hard disk H or other assembly to be processed can fit therein. The goal of the floor 22 and sidewalls 24 is containment of the hard disk H or other assembly but typically not to grip the hard disk H. The backstop 30 is located adjacent to the floor 22 and sidewalls 24 and includes a face 32 which generally faces the vibratory input tool 40. The backstop 30 provides containment similar to the floor 22 and sidewalls 24 of the retainer 20. The backstop 30 also acts to resist movement of the hard disk H responsive to vibratory energy acting upon the hard disk H by the vibratory input tool 40. Without the backstop 30, the vibratory input tool 40 could cause the hard disk H to merely move away from the vibratory input tool 40. Without maintaining contact between the vibratory input tool 40 and the hard disk H, vibratory energy cannot be separately transmitted into the hard disk H for excitation of the screws S and removal. The backstop 30 importantly acts to resist forces applied by the vibratory input tool 40 and so that a large portion of vibrational energy passing from the vibratory input tool 40 into the hard disk H remains within the hard disk H, rather than just causing movement of the entire hard disk H away from the vibratory input tool 40.

In one embodiment, a force F is applied to the backstop 30 to keep the backstop 30 in place. This force F could be applied by a spring or by a damper with the goal being maintaining of contact between the backstop 30 and the hard disk H, but avoiding the transmission of vibratory energy and potential damage to surrounding structures which support the retainer 20 and the backstop 30 thereof.

The vibratory input tool 40 generally includes a head 42 which is caused to rapidly vibrate relative to the tool 40. In one embodiment the vibratory input tool 40 is a pneumatic hammer. The pneumatic hammer can operate in a manner similar to that of a jack hammer, but typically smaller than jack hammers which are used for breaking up concrete foundations or slabs, but rather being more the size of a handheld pneumatic hammer. Sizing of the tool 40 can be adjusted to match size of the assembly being acted upon by the vibratory input tool 40.

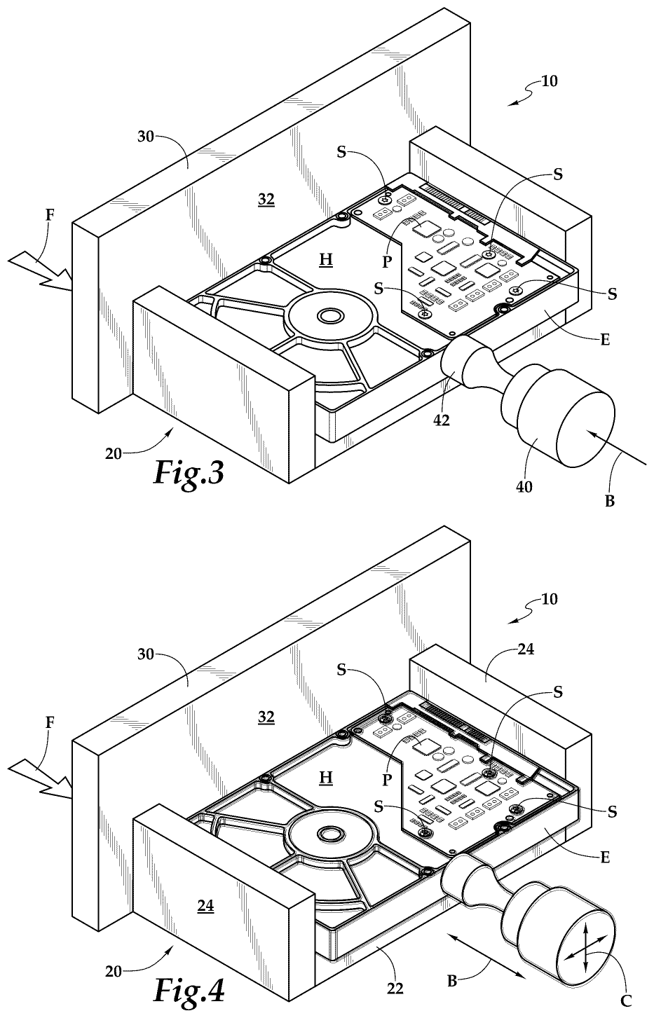

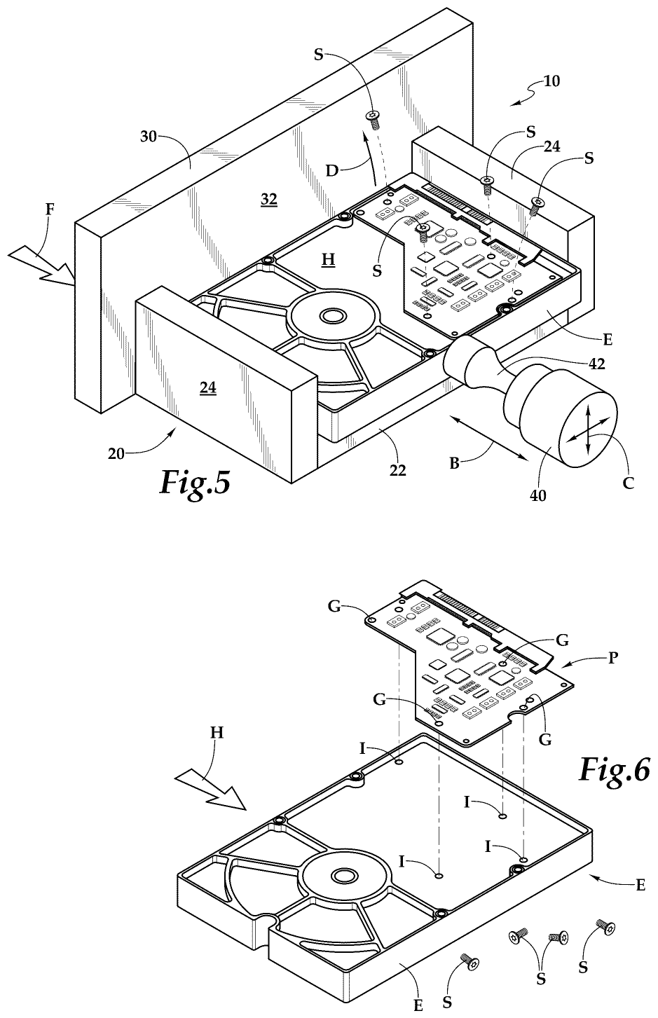

In use and operation, the system 10 can be utilized to remove screws S of the hard disk H in the following exemplary manner. Initially, the hard disk H or other assembly of components to be disassembled is brought adjacent to the retainer 20, such as by movement along arrow A of FIG. 1. The vibratory input tool 40 is then brought adjacent to the hard disk H, by movement along arrow B of FIGS. 3 and 4. Vibratory energy is then imparted upon the hard disk H by vibration of the vibratory input tool 40, such as along arrow C (and also or only along arrow B). The vibrational energy causes the screws S to become unscrewed and even typically jump away from the hard disk H (along arrow D of FIG. 5). The printed circuit board P or other component to be removed can then be typically merely lifted away from the other portions of the hard disk H (FIG. 6).

In an alternative embodiment, the system of this invention is exemplified by a vibratory threaded fastener removal machine 100. The purpose of the machine 100 is to simplify the process of sequentially feeding hard disks H through an operational area 110 where a system such as the system 10 (FIGS. 1-5) can act upon the hard disk H or other assembly. The machine 100 can then automatically discharge screws S or other threaded fasteners, as well as components of the assembly, out of the machine 100. The machine 100 can also contain sound resulting from operation of the machine 100, as the vibratory input tool 40 (and other machine systems) typically emits large amounts of sound which can be deleterious to personnel and have other negative effects.

The machine 100 generally includes an input chute 102 for input of hard disks H into the machine 100 and an output chute 108 for removal of the hard disk H, typically in the form of separated components, from the machine 100. Conveyors such as a first conveyor 104 and second conveyor 106 move the hard disk H within the machine 100 relative to an operational area 110. An outer case 105 contains elements of the machine 100 and helps to contain sound from operation of the machine 100. Insulation 107 can line interior surfaces of the outer case 105 to assist in sound absorption.

The input chute 102 generally communicates with an input opening in an outer enclosure provided by the case 105. Similarly, the output chute 108 typically communicates with an output chute leading out of the case 105. The output chute 108 also typically includes a funnel which tapers in area as it extends to the outlet location. Doors can occlude either the input, the output, or both in various embodiments.

While the chutes 102, 108 could lead directly to the operational area 110, typically the chutes 102, 108 merely provide access into and out of the case 105. At least one conveyor, and typically a first conveyor 104 and a second conveyor 106, move the hard disk H (or other assembly to be operated upon) from a first location to a second location. For the first conveyor, the first location is an exit from the input chute 102. The second location is an input into the operational area 110. For the second conveyor 106 the first location is an exit from the operational area 110 and the second location is adjacent to the funnel leading into the output chute 108.

The conveyors 104, 106 could be any of a variety of different conveyors. In FIG. 7 belt type conveyors, which can carry hard disks H and other assemblies resting upon an upper surface thereof, are shown. Other conveyors could grab hard disks H or other assemblies from above and convey them from a first location to a second location. Other types of conveyors could also alternatively be utilized rather than the specific first conveyor 104 and second conveyor 106 disclosed herein.

The operational area 110 generally functions similar to the system 10 (FIGS. 1-5). In this embodiment, the operational area 110 within the machine 100 includes a support channel 112 which has a horizontal floor 114 bounded on lateral sides by rails 116 extending up from the floor 114. Spacing between the rails 116 is generally similar to a thickness of a hard disk H or other assembly to be operated upon by the operational area 110. Holes in the floor 114 are sized to allow heads 122 of hammers 120 to extend upwardly therethrough. Typically, two such holes are provided so that heads 122 of two hammers 120 can pass up through the floor 114 and come into contact with an outer enclosure E of a hard disk H, or other assembly to be acted upon.

The hammers 120 could as one option be a single hammer 120 with two heads 122. It is also conceivable that a larger or smaller number of heads 122 could be provided, either with one head 122 for each hammer 120, or with multiple heads 122 for each hammer 120. The hammers 120 preferably act generally vertically upwardly with motion along arrow C and arrow B. Arrow B generally represents movement of the hammers 120 into position through the floor 114 to come into contact with the hard disk H, and movement C generally represents vibrational movement to impart vibrational energy from the hammers 120 through the holes in the floor 114 and into the hard disk H that is resting upon the floor 114 in between the rails 116 within the operational area 110.

These hammers 120 are preferably supported from below by isolators 124 which are, in this example, in the form of resilient masses typically with a relatively low Shore hardness, so that vibrational energy from operation of the hammers 120 is not effectively transmitted to the case 105. This impedes damage to the outer case 105 and other elements of the machine 100 within the case 105, such as being vibrationally disassembled or otherwise damaged by operation of the hammers 120.

A pneumatic source 140, such as an air compressor, is also preferably located within the case 105 and has air supply lines 150 leading to the hammers 120 to power the hammers 120. In alternate embodiments, the hammers 120 could be powered in a manner other than pneumatically, such as electric power, hydraulic power or transmission of mechanical power to the hammers 120 to cause them to vibrate appropriately according to this invention.

A backstop 130 is preferably located above the operational area 110 and in the form of at least one (and typically two) dampers 133 supporting a reference plate 132 at a lower end thereof. This reference plate 132 can come into a contact with a side of the hard disk H or other assembly opposite the hammers 120. This reference plate 132 optionally can be moved up and down such as by supplying or relieving air pressure supplied along air supply lines 150 from pneumatic source 140 to the dampers 133. The dampers 133 thus act both as positioners for the reference plate 132 and also as dampers to absorb vibrational energy which might otherwise pass up through the backstop 130 assembly and cause damage to adjacent structures.

Furthermore, the dampers 133 protect the hard disk H or other assembly to be disassembled from having its outer case ruptured by the hammers 120 (which tends to cease/diminish useful vibration of the disk H). In addition to the dampers 133, a “shimmy” ongoing slow lateral movement of the hard disk H by the conveyor 210 distributes hammer 120 energy to different parts of the hard disk H, to also reduce risk of disk H rupture. Such shimmy also adjusts vibrational harmonics to increase propensity for screw S removal and subcomponent disassembly.

The backstop 130 is typically mounted to an upper wall or at least upper portions of the outer case 105 of the machine 100. Movement of the backstop 130 and associated reference plate 132, along arrow F, is facilitated both by positioning of the dampers 133 down onto the hard disk H and also represents a function of the dampers 133, including movements up and down to absorb vibrational energy from the hammers 120. The reference plate 132 of the backstop 130 helps to keep the hard disk H adjacent to the heads 122 of the hammers 120 for maximum effectiveness of the hammers 120 and importing vibrational energy onto the hard disk H to cause screw S removal.

In use and operation and with continuing reference to FIG. 7, details of operation of the machine 100 are described according to this example embodiment. Initially, a hard disk H or other assembly to be disassembled is passed into the input chute 102 along arrow J. The first conveyor 104 then moves the hard disk H along arrow K into the operational area 110. The dampers 133 are then caused to lower the reference plate 132 into contact with upper portions of the hard disk H (by movement along arrow F). The hammers 120 are then caused to move upward along arrow C until the heads 122 of the hammers 120 come into contact with the hard disk H, by passing up through holes in the floor 114 of the operational area 110.

The hammers 120 are then activated to cause a vibrational energy to be imparted, along arrow C, up into the hard disk H. This energizes the screws S and causes them to become unscrewed and for disassembly of components of the hard disk H (or other assembly) from each other. The screws S can be collected adjacent a floor of the case 105 or in some other screw S catching receptacle below the operational area 110.

Components of the hard disk H are then outputted onto the second conveyor 106 which conveys these components to the output chute 108 (along arrow L) and along arrow M. Finally, discharge out of the machine 100 for the components occurs along arrow N. In various embodiments, and for various different assemblies, both screw removal and de-bonding of bonded and/or welded components can occur by imparting of vibrational energy utilizing the machine 100. A significant portion of sound generated by operation of the hammers 120 and operation of other portions of the machine 100 (such as the pneumatic source 140 in the form of an air compressor) can be absorbed within the outer case 105 of the machine 100. One sound absorption system uses sound insulation 107 on interior walls of the case 105 and optionally other locations within the case 105.

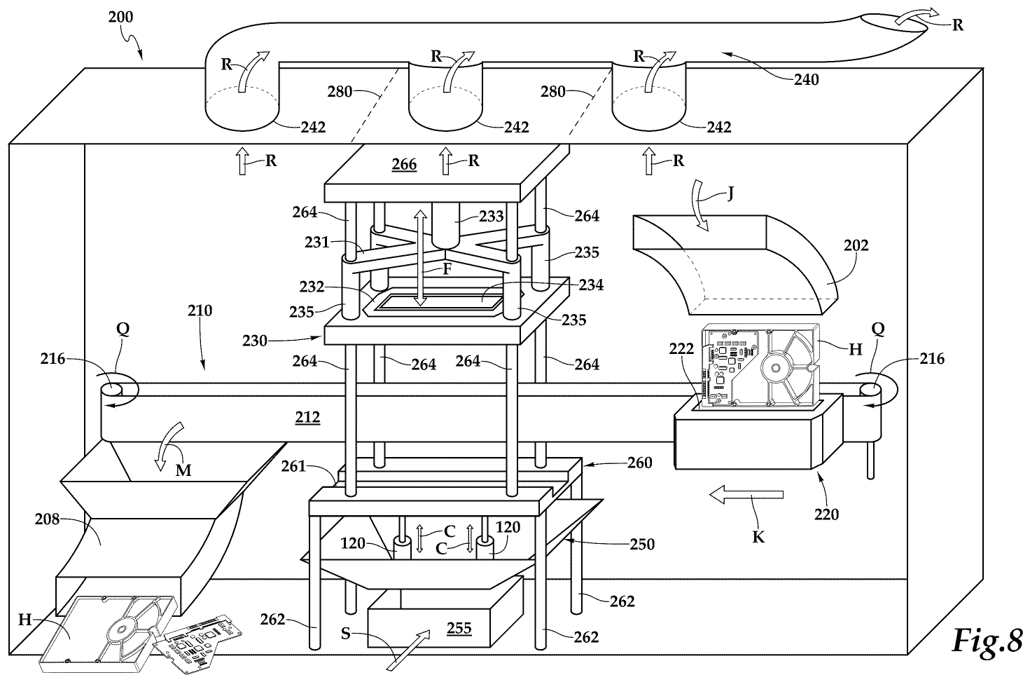

With particular reference to FIG. 8, details of a second embodiment vibratory threaded fastener removal machine 200 are described. Features of this machine 200 are in some instances modified or distinct from features of the machine 100 described above, with such features being optionally substituted between these machines 100, 200 to produce various different further alternative embodiments of this invention.

With the second embodiment machine 200, a conveyor 210 is provided which includes a belt 212 that rotates about spindles 216 which rotate about vertical axes of rotation. The belt 212 extends from an entry region of the machine 200 through a central operational area to a discharge region of the machine 200. In one embodiment, the belt 212 is largely contained within a housing with only a forward facing portion of the belt 212 exposed. The machine 200 can include vertical divider walls to separate the regions/areas of the machine, such as below divider lines 280 and adjacent to lateral sides of a debris funnel 250. The divider walls are not shown so that other structures can be more clearly seen. Ports in such divider walls can be located adjacent to the conveyor 210 to allow for transport of hard disk H or other items to be disassembled through the machine 200. The divider walls help to contain debris produced by hammer 120 operation and can be insulated to help keep sound from emanating too loudly from the machine 200. Whiskers can be provided at the ports to further contain debris.

A carrier 220 is mounted to the belt 212. Thus, the carrier 220 moves horizontally when the conveyor 210 is activated. Sensors and a control system control operation of the conveyor 210 so that the carrier 220 is moved horizontally between different regions of the machine 200. The carrier 220 is particularly configured to hold a hard disk H or other device which is to be disassembled, such as by having threaded fasteners removed therefrom.

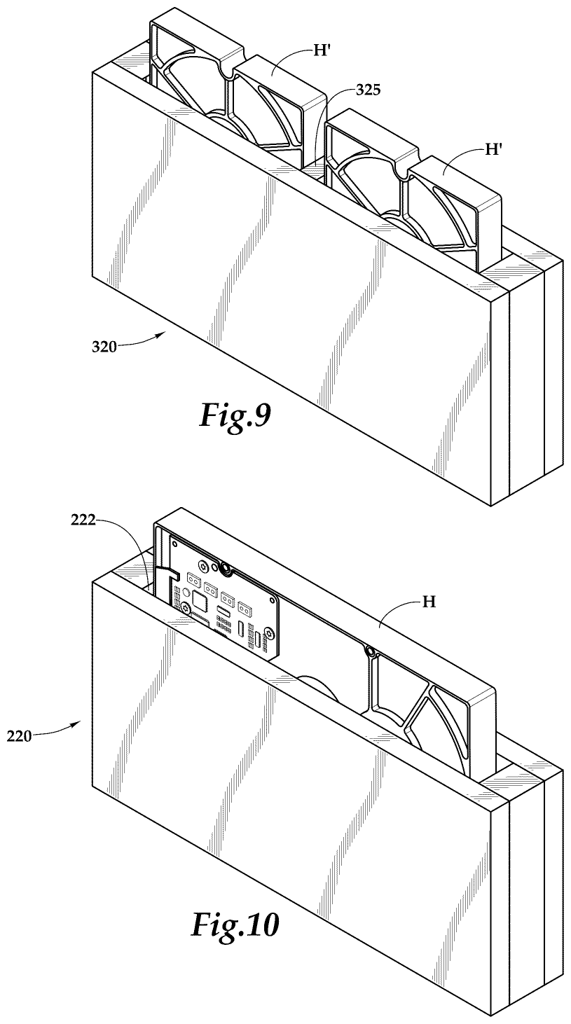

Various embodiments of the carrier 220 are shown in FIGS. 9 and 10. FIG. 10 shows a basic carrier 220 with a central slot 222 having an open top into which a hard disk H or other item to be disassembled can be placed. This slot 222 can be aligned with an input chute 202 of the machine 200 so that items such as hard disks H can be routed from outside the machine 200 and into the slot 222 of the carrier 220.

Slot 222 is preferably only slightly larger than the hard disk H or other item so that the hard disk H is held in position for operation thereon. Lateral sides of the carrier 220 keep the hard disk H or other item in this desired position. Typically, this desired position and orientation for the hard disk H or other item involves largest surfaces of the item facing horizontally and perpendicular to the direction of item movement through the machine 200.

A lower surface of the carrier 220 has at least holes in a lower surface thereof (at least one hole) positioned to be aligned with the hammers 120 (at least one hammer 120) which act upon the item for disassembly thereof, as described in detail above, such as with regard to the machine 100. As one option, a lower surface of the carrier 220 can be entirely open and the carrier 220 can be located just above a horizontal support surface. The horizontal support surface could have a position and orientation similar to an upper surface of the belts 104 and 106 of the machine 100, but merely stationary and allowing the item such as a hard disk H to slide thereon while the carrier 220 advances the item laterally, under action by the belt 212. As another option, such a support surface could be a moving support surface such as a moving belt. As a further option, the carrier 220 could include active gripping structures which grip and hold the hard disk H or other item securely within the carrier 220 until it is located above the at least one hammer 120 in the central operational area of the machine 200.

With regard to FIG. 9, an alternate carrier 320 is provided which includes a central divider 325 which separates the slot into two separate slots on either side of the divider 325. Such an alternate carrier 320 can thus hold two separate hard disks H or other items of a smaller size therein for simultaneous disassembly thereof, especially when a pair of hammers 120 are provided within the machine 200 at the central operational area thereof.

When the conveyor 210 is an operation, it causes the belt 212 to move the carrier 220 laterally back-and-forth within the machine 200. The typical operational method would involve the conveyor 210 first locating the carrier 220 beneath the input chute 202 for loading with a hard disk H or other item to be disassembled. Once loaded, the conveyor 210 would be activated to move the carrier 220 into the operational area above the hammers 120. The hammers 120 would then be activated and act upon the hard disk H or other item for vibratory removal of threaded fasteners contained therein, and potentially also vibratory disassembly of other components within the hard disk H. By keeping a lower portion of the carrier 220 largely open, sub-components which are removed from the hard disk H or other item can freely fall down out of the carrier 220. The conveyor 210 can then advance the carrier 220 to a discharge region, such as above the output chute 108, for discharge of larger portions of the hard disk H or other item out of the machine 200.

Preferably, a debris funnel 250 is located beneath a table 260 which generally replaces the support channel 112 of the machine 100 in the second embodiment machine 200 of FIG. 8. This debris funnel 250 collects small subassemblies and debris which fall off of the hard disk H or other item to be disassembled under operation of the hammers 120. The debris funnel 250 is located over a drawer 255. This drawer 255 can be moved laterally into and out of the machine 200 for periodic removal of subassemblies and debris which fall down through the debris funnel 250 into the drawer 255. Such subassemblies (and screws, etc.) can then be appropriately reused and/or recycled, depending on their condition after vibrational disassembly.

Some debris/dust is typically created while the hammers 120 act on the hard disk H or other item to be disassembled. To keep such small and very lightweight particles from merely settling onto all horizontal surfaces and requiring periodic cleaning thereof, most preferably the machine 200 of FIG. 8 includes and exhaust hood 240. The exhaust hood 240 can include an exhaust fan therein. Various air inlets into the machine 200 can cause a flow path for air within the machine 200 to be generally upward and out of the exhaust hood 240. In this way, fine particles produced by operation of the hammers 120 on the hard disk H or other item to be disassembled are generally being continuously evacuated from within the machine 200 (which machine 200 is generally typically entirely enclosed otherwise), except for small openings associated with the input chute 102 and output chute 108.

Such an outer enclosure helps to contain this debris and also assists in noise suppression for noise associated with machine 200 operation, and also helps to maintain a safe environment for individuals located near the machine 200. In one embodiment, the exhaust hood 240 includes three separate inlets 242, including a central inlet over an operational area of the machine 200 and additional inlets 242 within an inlet region and an outlet region of the machine 200. The exhaust hood 240 can lead to a filter element or settling chamber for collection of dust and debris evacuated from the machine 200 by the exhaust hood 240.

The carrier 220 is returned to its starting point after a hard disk H or other item to be disassembled has been routed from an inlet region through the operational area, acted upon by the hammers 120, and then advanced to the outlet region for discharge from the machine 200 via the output chute 208. Such return of the carrier 220 is provided by reversing operation of the conveyor 210 and causing a belt 212 to move in an opposite direction, moving the carrier 220 back to its starting location beneath the input chute 102. The process implemented by the machine 200 can then be repeated.

As another optional use for the conveyor 210, small movements of the carrier 220 can be provided within the operational area adjacent to the hammers 120 during a cycle where the hammers 120 are acting upon the hard disk H or other item to be disassembled. For instance, the carrier 220 could first be moved to a location centered over the hammers 120. After a first phase of operation of the hammers 120, the conveyor 210 could cause the carrier 220 to move slightly in a forward or a reverse direction. The hammers 120 would then continue to work on slightly different locations upon the hard disk H or other item to be disassembled.

As the machine 200 operates upon different hard disks H or other items to be disassembled, data can be gathered as to which locations on the hard disk H or other item are best acted upon by the hammers 120 for most efficient threaded fastener removal or other disassembly. Furthermore, hammer 120 operation including vibrational, amplitude, vibrational, frequency, etc. (or multiple different amplitudes and frequencies) can be monitored to determine which values for these parameters are most effective. For some hard disks H or other items, it may be desirable to utilize the conveyor 210 and carrier 220 to slightly move the hard disk H or other item, so that the hammers 120 can act on different portions of the hard disk H or other item for most effective results.

As a further option, at least one microphone can monitor a sound associated with operation of the hammers 120. Sound changes indicative of screw removal or other subassembly removal can be detected by such a microphone and then the hammer 120 operating process can be terminated responsive to sounds indicating completed disassembly, rather than some preset amount of time. Similarly, at least one camera could be utilized for monitoring the hard disk H or other item, and ceasing hammer 120 operation when satisfactory disassembly has been seen by the camera to have been achieved.

In this second embodiment machine 200, a table 260 within the central operational area has holes passing therethrough, through which holes the hammers 120 extend upwardly and act (along arrow C) upon the hard disk H or other item to be disassembled. A channel 261 in an upper surface of the table 260 is optionally provided to keep the hard disk H located above these holes. Columns 262 extend up from a floor of the machine 200 to support this table 260 just below the conveyor 210, so that the carrier 220 can pass over the table 260. Preferably, the columns 262 hold the table 260 in fixed position within the machine 200. Upper columns 264 extend up from the table 260 and support a backstop assembly 230 at an upper portion of the central operational area of the machine 200. In particular, in this embodiment the upper columns 264 have upper ends joined together by a top plate 266.

The backstop assembly 230 is movably attached to this top plate 266 so it can move up and down under control of a machine 200 controller. Such movement could as one option be controlled by a pneumatic cylinder 233 (along arrow F). The backstop assembly 230 moves a backstop housing 232 down along with a block 234 which contacts an upper surface of the hard disk H or other item to be disassembled, just before commencement of operation of the hammers 120.

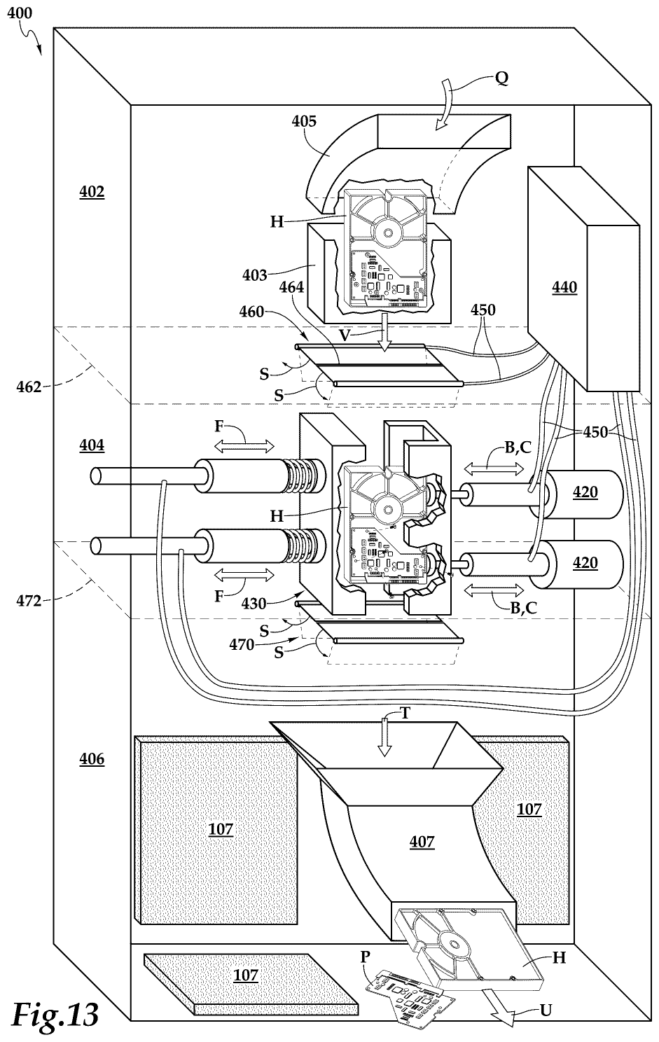

Which particular reference to FIG. 12, one embodiment of backstop housing 232 and block 234 are disclosed. This backstop assembly 230 includes the peripheral housing 232 which is fixed relative to the movable backstop assembly 230. The central block 234 is attached by springs 238 within a central portion of the housing 232. The block 234 is thus somewhat of a floating structure. A groove 236 preferably runs along an undersurface of the block 234. This groove 236 is sized to be slightly larger than the hard disk H or other item to be disassembled, so that it can fit into this groove 236 and be somewhat supported laterally while it is primarily being supported on an upper surface thereof opposite the hammers 120.

While the hammer 120 is operating on the hard disk H or other item to be disassembled, the block 234 of the backstop assembly 230 keeps the hard disk H or other item to be disassembled adjacent to the hammers 120. The springs 238 preferably are oriented along central axes which are horizontal. Thus, the springs 238 are loaded perpendicular to central axes thereof during operation of the machine 200. The springs 238 can be held in place at each end by residing within bores or by utilizing some form of spring fastener or central flexible alignment post. Beneficially, such an orientation avoids the need to lubricate vertical shaft to accommodate vertical vibratory motion of the backstop assembly 230 (including an X-frame 231 and sleeves 235) responsive to operation of the hammers 120. Instead, these horizontally oriented springs isolate the vertical energy imparted by the hammers 120 from being passed onto the backstop assembly 230 and columns 262, 264, helping to isolate this vibrational energy from the hammers 120 from causing vibrational damage to various different sub-systems of the machine 200. The X-frame 231 and sleeves 235 thus only need to move the backstop assembly 230 into position and then remain fixed relative to the top plate 266 during hammer 120 operation. The housing 232 could be permanently fixed to or formed with the sleeves 235 or could be removably attachable. The housing 232 and block 234 typically are positioned slightly lower than other portions of the assembly 230.

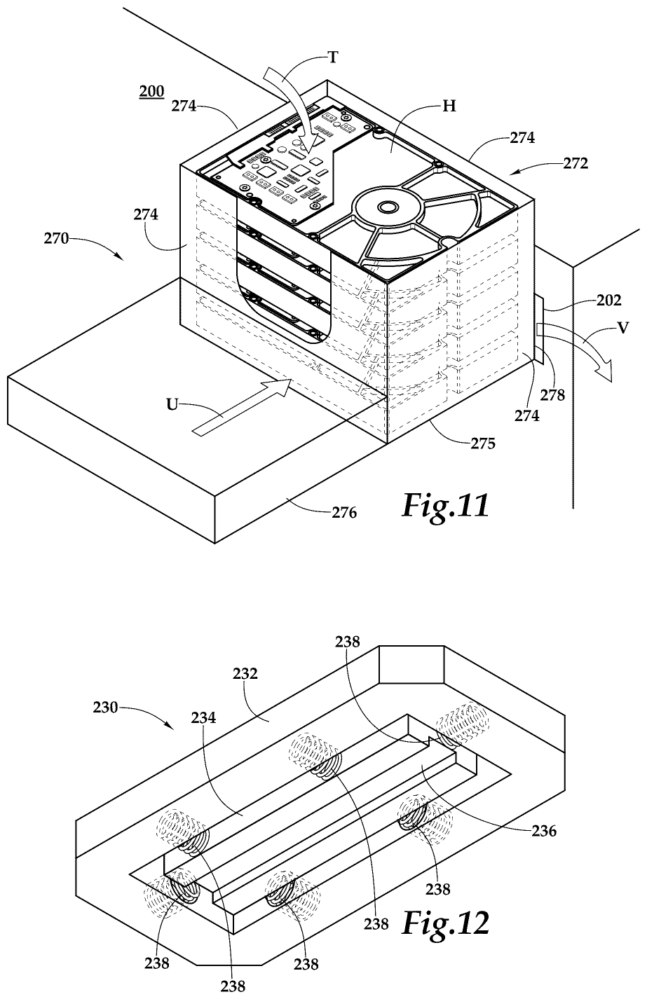

With particular reference to FIG. 11, a batch loader 270 is shown. This batch loader 270 can be mounted adjacent to the input chute 202 of the machine 200 which is shown in this second embodiment of FIG. 8 in an upper right corner of a front face of the machine 200, but could be otherwise located relative to surfaces and portions of the machine 200. The batch loader 270 allows for multiple hard disks H or other items to be stacked therein and to be operated upon by the machine 200, without requiring an attendant to manually insert each hard disk H into the machine 200.

With this particular batch loader 270, a magazine 272 is provided extending vertically up from a base 275. This magazine 272 is sized so that hard disks H or other items to be disassembled can be conveniently stacked therein (along arrow T of FIG. 11). Different magazines 272 of different shapes and sizes could be provided, potentially removably attachable to other portions of the batch loader 270 or provided in separate batch loaders 270, removably attachable to the machine 200, to accommodate different shape and size items to be disassembled. While FIG. 11 shows a magazine that holds five hard disks H, larger (or smaller) magazines 272 could be provided for holding a larger (or smaller) number of hard disks H.

Walls 274 of the magazine 272 keep the hard disks H or other items to be disassembled in a vertical column within upper portions of the batch loader 270. A pusher 276 is provided on a side of the base 275 of the batch loader 270 opposite of an exit 278, which is located adjacent to the input chute 202 of the machine 200. This pusher 276 includes a mechanism which can be coordinated with operation of the machine 200 to impart a lateral force to push on an item at the bottom of the magazine, pushing it into the input chute 202 (along arrow U).

This pusher 276 would typically be a mechanical block having a shape similar to that of the items to be disassembled, which is actuated to move laterally and push on a lowermost item in the stack of items within the magazine 272, to push this lowermost item into the input chute 202 of the machine 200 (along arrow V of FIG. 11). This pusher 276 element would then be retracted by the actuator, so that the items within the magazine 272 could move down under action of gravity, and so that a new lowermost item within the magazine 272 would then be ready to be advanced into the input chute 202 when the machine 200 is ready to receive it.

The actuator of the batch loader 270 is preferably controlled along with the machine 200 so that when the machine 200 is ready to receive a new item to be disassembled, a signal sent to the batch loader 270 and the batch loader 270 then operates to cause a new item to be pushed into the input chute 202. Other parts of such a control system could include a warning when the magazine 272 is empty, or about to become empty, which warning can be passed along to appropriate personnel so they are notified to return to the machine 200 and reload the magazine 272. In this way, efficient machine 200 operation can be maintained with a minimum of human presence required. Furthermore, either in addition to the batch loader 270 or as an alternative to the batch loader 270, various conveyors can be provided adjacent to the machine 200 which could sequentially deliver to the machine 200 various different items to be disassembled. Such conveyors could load the magazine 272 of the batch loader 270 or feed items directly into the input chute 202.

With some hard disks H and other items to be disassembled, a primary goal is removal of screws S or other threaded fasteners. However, in some instances paper or metal foil is applied over heads of the threaded fasteners. This cover often has a gap above the screws S, so the screws S can still be vibrationally removed. Otherwise, the foil can be very difficult to remove. This invention thus typically avoids this cover removal process. In the case of a paper cover, such a paper cover is often adhesive backed paper, such as a label. Such a paper label on the item can prevent (or at least make significantly more difficult) the threaded fastener removal process of this invention. Accordingly, in one embodiment a wire brush is first utilized to brush off paper overlying any threaded fastener heads. Such a wire brush can in one embodiment be a manual brush and manual force is applied by user to provide for paper removal. As an alternative, the wire brush could be mechanized and could be incorporated into the machine 200, such as within a portion of the input chute 202, or could occur in a separate mechanized step such as along a feed conveyor feeding hard disks H or other items to the input chute 202.

In some embodiments, it is desirable for more disassembly to occur rather than merely removal of screws or other threaded fasteners. For instance, hard disks H include magnets which can be beneficially recycled and/or reused. Even if not recycled or reused, these magnets can impede disassembly because of the strong magnetic forces which they impart upon other magnets and other sub-components which may be desired to be disassembled, one from the other. In one embodiment, to eliminate (or at least reduce) such magnetic forces and to encourage the disassembly process, the hard disk H or other item to be disassembled can first be demagnetized. A demagnetization station could be provided within the machine 200, such as within the input chute 202, or could be a separate demagnetization station outside of the machine 200 and acting upon items to be disassembled before they arrive at the machine 200 for disassembly therein.

While the hammers 120 as well as the backstop assembly 230 and conveyor 210 are described in various embodiments herein as being powered pneumatically, it is understood that other power sources could alternatively be provided. These power sources could be different for the different elements of the machines 100, 200 or could be a common source of power. Options for such provision of power to these elements of the machines 100, 200 include electric power, hydraulic, magnetic, AC field power, or other power sources to cause the movements desired within the machines 100, 200.

With particular reference to FIG. 13, an alternative embodiment of the vibratory threaded fastener removal machine 100 is shown in the form of a vertical vibratory threaded fastener machine 400. This machine 400 is in many respects similar to the machine 100 of FIG. 7, except as specifically described herein. By orienting the machine 400 with a vertical hard drive H pathway (along arrows R and T of FIG. 13) down through the machine 400, gravity forces can provide some or all of the motive force needed to move the hard drive H (or other item to be disassembled) from input into the machine 400 to output from the machine 400. The machine 400 is thus simplified to primarily only needing to operate the hammers 420. One category of items to be disassembled is hard disk H caddies which are exterior to a housing of the hard disk H and can be removed by input of a vibratory energy according to this invention.

The machine 400 is divided into three zones, including a feed zone 402, an operational zone 404 and a discharge zone 406. The operational zone 404 is located beneath the feed zone 402 and above the discharge zone 406. The hammers 420 are located within the operational zone 404. Dividers 462, 472 are located between these zones 402, 404, 406.

The feed zone 402 provides a region for inputting of hard disks H or other items to be disassembled. Typically this inputting is in the form of an input chute 405. In the embodiment shown, the input chute 405 has a curving form and extends from an entry slot in an upper front of the machine 400, where the hard disks H or other items to be disassembled can pass into the machine 400 (along arrow Q of FIG. 13). At a lower end of the input chute 405, a feed tube 403 is optionally provided to keep the hard disk H or other item oriented within a vertical plane as it extends down (along arrow R of FIG. 13) to the divider 462 between the feed zone 402 and the operational zone 404.

In this embodiment, a top gate 460 is provided beneath the feed tube 403 and generally at the divider 462. The top gate 460 is generally configured like a trap door with at least one pivoting panel. The pivoting panel pivots between a substantially horizontal orientation, which blocks a port 464 passing through the divider 462. In the embodiment shown, two such pivoting door panels are provided which pivot (along arrow S of FIG. 13) between a closed generally horizontal orientation, and an open generally vertical orientation. At least one door pivots at least enough to allow the item such as a hard disk H to pass through the top gate 460 when opened. In one embodiment, a pneumatic source 440 feeds air under pressure to actuators associated with the door panels to cause opening and closing of the top gate 460.

A space between the hammers 420 and a backstop 430 is located just below the top gate 460. As needed, a further feed tube (or other guiding structures) can be provided to generally keep the hard disk H or other item to be disassembled within its vertical plane orientation as it falls down when the top gate 460 is opened, and into the operational zone 404. A bottom gate 470 is provided just beneath this space between the hammers 420 in the backstop 430, such that the item to be disassembled can fall down and rest upon the closed bottom gate 470, holding the item in place while acted upon by the hammers 420 and backstop 430. When this action is complete, the bottom gate 470 can be caused to transition to an open state (along arrow S of FIG. 13 for instance) to allow the item and components removed therefrom to fall down through the bottom gate 470 from the operational zone 404 into the discharge zone 406. In one embodiment, the bottom gate 470 is similar in configuration to the top gate 460, but is controlled separate from the top gate 460 for opening and closing of the top gate 460 and bottom gate 470 independent of each other.

An output chute 407 and associated funnel can receive the item (typically disassembled into separate components and/or housings) under gravity forces as it falls down through the bottom gate 470. An output chute 407 in one embodiment has a curving form leading to an output opening in a lower front portion of the machine 400 for the hard disk H and printed circuit board P (or other removed components) to be discharged from the machine 400 (along arrow U of FIG. 13). In one embodiment, the divider 472 is in the form of a screen with large enough apertures therein that small components can pass through. Such small components might be ejected with significant kinetic energy from a space between the hammers 420 and backstop 430 to be laterally displaced away from the bottom gate 470. Such small components can still fall down out of the operational zone 404 and into the discharge zone 406 when the divider 472 is a screen (or no divider 472 is provided at all as an option). In one embodiment, the funnel associated with the output chute 407 is sufficiently large that any items falling down through from the operational zone 404, and not just through the bottom gate 470, will be gathered and channeled through the output chute 407. In another embodiment, the output chute 407 can be primarily for the item and large components thereof, while any smaller components ejected during disassembly with high kinetic energy laterally away from the output chute 407 can be separately collected in a separate perimeter debris collection tray. Such smaller ejected items might include threaded fasteners and other small components of the item being disassembled.

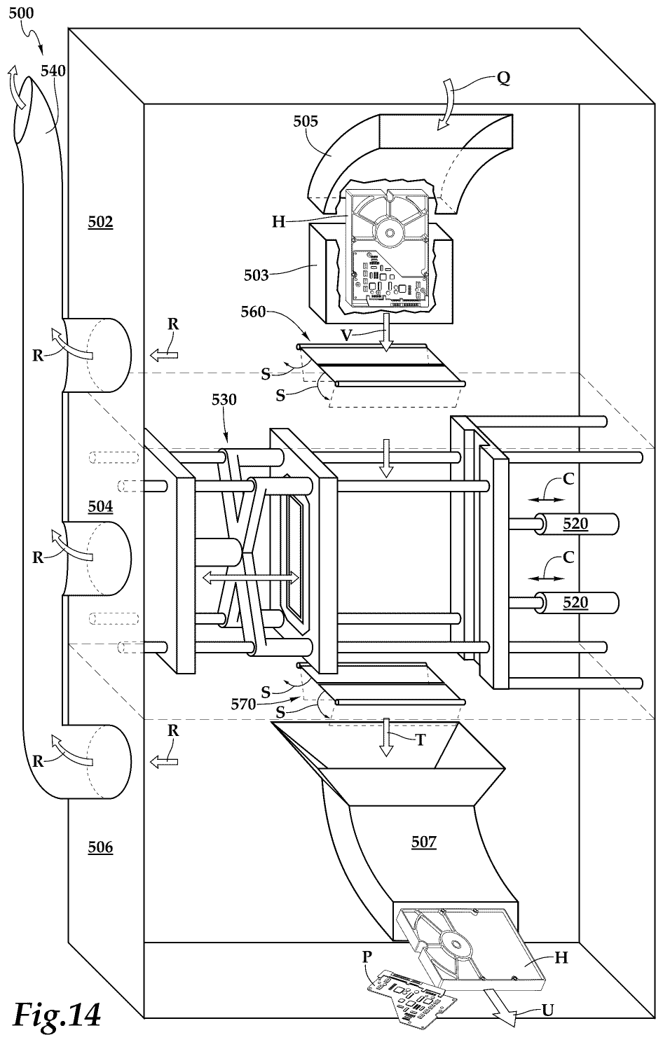

With particular reference to FIG. 14, a machine 500 is described which is a vertical analog to the second embodiment machine 200 of FIG. 8. Portions of this machine 500 which are described in detail herein are generally similar to those which could be provided in the second embodiment machine 200 of FIG. 8. Furthermore, the machine 500 is similar to the vertical vibratory threaded fastener removal machine 400 of FIG. 13, except where shown and described distinctly herein.

The machine 500 includes an operational area 504 below a feed zone 502 and above a discharge zone 506. The operational zone 504 is where hammers 520 and the backstop 530 are located. These hammers 520 and backstop 530 have configurations similar to the corollary elements of the machine 200 of FIG. 8, except that these components, including the hammers 520 and backstop 530 are oriented horizontally spaced from each other, rather than vertically spaced from each other, and with a generally mostly vertical pathway for items to be disassembled passing therebetween.

An exhaust hood 540 is also shown in this machine 500 embodiment, located on a left side of an outer housing of the machine 500. As an alternative, this exhaust hood 540 could be in a top surface of the machine, if desired, for routing of exhaust along arrow R therefrom, such as potentially dust and fine particulates which might be generated by the vibratory threaded fastener removal tool, such as the hammers 520.

A top gate 560 and bottom gate 570 are provided between the various zones of the machine 500 to control flow of items such as hard disks H being disassembled in the machine 500. A feed tube 503 can be provided below the input chute 505 to keep the hard drive H or other item to be disassembled in a generally vertically oriented plane as it passes down from the feed zone 502 into the operational zone 504 between the hammers 420 and backstop 430. The backstop 430 and at least one hammer 520 can then act upon the item to be disassembled, causing threaded fasteners to be vibratorily removed from the item and potentially for removal of components of the item to be at least partially separated from the housing or other portions of the item (or to remove the item from an exterior structure, such as a caddy). Thereafter, a bottom gate 570 can be opened to allow the item (and components thereof) to pass down into the output chute 507 for discharge from the machine 500.

With the vertical vibratory threaded fastener removal machines 400, 500 (FIGS. 13 and 14) items such as hard disks H can merely be fed into the entry of the input chute 405, 505 and be allowed to stack up one upon the other, as long as the top gate 460, 560 is closed. A pneumatic actuator signal (or other control signal) can cause the top gate 460, 470 to transition to an open state long enough to allow one item to fall down into the operational zone between the hammers 420, 520 and the backstop 430, 530. The top gate 460, 560 closes before a second item can fall down through the top gate 460, 560, in a preferred embodiment. In alternative embodiments, items could merely be stacked one upon the other as they feed through the operational zone 404, 504, and without requiring closing of the top gate 460, 560.

The bottom gate 470, 570 would be closed so that the item to be disassembled after falling through the top gate 460, 560, is held above the bottom gate 470, 570 and is held in position between the hammers 420, 520 and the backstop 430, 530 while disassembly occurs through vibratory input from the hammers 420, 520. After disassembly is complete, the bottom gate 470, 570 is opened to allow the item and separated components thereof to fall down into the output chute 407. The bottom gate 470, 570 then transitions to a closed state again. Thereafter, the top gate 460, 560 can be opened to allow a next item to be disassembled to pass from the feed zone 402, 502 into the operational zone through the top gate 460, 470. The process then repeats itself.

As an alternative to the input chute 405 (or in addition thereto), a feed magazine could be provided which would be configured to hold multiple items and feed them sequentially into the input chute 405, 505 or otherwise into the feed zone 402, 502 to be aligned and ready for passage into the operational zone 404, 504 for disassembly thereof. In this way, an operator could merely fill the magazine periodically and then leave the machine 400, 500 unattended to automatically perform its disassembly function. The operator would then merely return periodically to refill the magazine with items to be disassembled. Such an operator could also periodically empty any collection bin of disassembled parts of the items being disassembled. As a further alternative, other forms of feeders, such as conveyor belts, could be located adjacent to the machine, 400, 500 for periodic and automatic feeding of items into the machine 400, 500 for disassembly thereof, and with a lesser requirement for operator interaction.

This disclosure is provided to reveal a preferred embodiment of the invention and a best mode for practicing the invention. Having thus described the invention in this way, it should be apparent that various different modifications can be made to the preferred embodiment without departing from the scope and spirit of this invention disclosure. When embodiments are referred to as “exemplary” or “preferred” this term is meant to indicate one example of the invention, and does not exclude other possible embodiments. When structures are identified as a means to perform a function, the identification is intended to include all structures which can perform the function specified. When structures of this invention are identified as being coupled together, such language should be interpreted broadly to include the structures being coupled directly together or coupled together through intervening structures. Such coupling could be permanent or temporary and either in a rigid fashion or in a fashion which allows pivoting, sliding or other relative motion while still providing some form of attachment, unless specifically restricted.

What is claimed is:

1: A method for disassembly of an item with at least one component attached by at least one threaded fastener to other portions of the item, the method including the steps of:
feeding the item into an input of a machine configured to disassemble items;
bringing a vibratory input tool into contact with a portion of the item;
causing the vibratory input tool to vibrate against the item until the at least one threaded fastener is removed and the component is separated from the item; and
discharging the item and the component from the machine.

2: The method of claim 1 wherein the component being removed is a printed circuit board (PCB) screwed to a housing of the item.

3: The method of claim 2 wherein the item is a hard disk and the PCB is screwed to the housing of the hard disk.

4: The method of claim 3 wherein a plurality of screws attach the PCB to the housing through a plurality of standoffs affixed to the housing, each standoff including a threaded bore within an interior thereof, and all of the screws being removed by input from the vibratory input tool against the housing of the hard disk.

5: The method of claim 1 wherein said bringing step is preceded by a step of at least partially removing paper covering at least one of the threaded fasteners.

6: The method of claim 1 wherein said bringing step is preceded by a step of placing the item into a feed zone of the machine, the feed zone above an operational zone where the vibratory input tool is located.

7: The method of claim 6 wherein a top gate is located between the feed zone and the operational zone; and
including the step of opening the top gate to allow the item to fall down into the operational zone.

8: The method of claim 7 wherein a backstop is located facing the vibratory input tool with the item located between the vibratory input tool and the backstop when in the operational zone.

9: The method of claim 8 wherein the backstop is mounted via an energy absorber to a reference surface.

10: The method of claim 9 wherein the top gate includes a trap door assembly with at least one pivoting door element which pivots about a horizontal axis to open the trap door enough to allow the item to fall into the operational zone.

11: The method of claim 10 wherein a bottom gate is located below said top gate and below said vibratory input tool, said bottom gate selectively openable to allow the item and the component to fall toward an output from the machine.

12: The method of claim 11 wherein the top gate and the bottom gate are opened at separate times to control flow of multiple items into and out of the operational zone.

13: A machine for removing threaded fasteners holding a component within an item, the machine comprising in combination:
a feed zone above an operational zone and discharge zone below said operational zone;
a vibratory input tool located within said operational zone; and
a pathway from the feed zone through the operation zone to the discharge zone, the pathway sized to allow items to pass adjacent to the vibratory input tool.

14: The tool of claim 13 wherein said vibratory input tool includes a head with a flat face, which head vibrates relative to a body of said vibratory input tool.

15: The tool of claim 14 wherein said vibratory input tool has a frequency of vibration that is better at removing the threaded fasteners than at least one other frequency.

16: The tool of claim 13 wherein a backstop is located within said operational zone and opposite said vibratory input tool to keep the item adjacent to an output head of the vibratory input tool.

17: The tool of claim 16 wherein said backstop is supported by springs.

18: The tool of claim 17 wherein said springs are helical in form with a central axis oriented non-parallel with a direction of motion of said vibratory input tool.

19: The tool of claim 13 wherein a top gate is located between said feed zone and said operational zone, said top gate openable to allow an item to fall from said feed zone into said operational zone.

20: The tool of claim 19 wherein said vibratory input tool is oriented to impart vibratory energy into the item horizontally.
